(19) United States
(12) Patent Application Publication
(10) Pub. No.: US 2021/0175052 A1
(43) Pub. Date: Jun. 10, 2021

(54) SUBSTRATE PROCESSING APPARATUS, BEVEL MASK AND SUBSTRATE PROCESSING METHOD

(71) Applicant: ASM IP Holding B.V., Almere (NL)

(72) Inventors: Yuki Takahashi, Tokyo (JP); Dai Ishikawa, Tokyo (JP)

(21) Appl. No.: 17/109,080

(22) Filed: Dec. 1, 2020

Related U.S. Application Data
(60) Provisional application No. 62/945,061, filed on Dec. 6, 2019.

(51) Int. Cl. H01J 37/32; H01L 21/02

(52) U.S. Cl. CPC H01J 37/32651; H01L 21/02274

(57) ABSTRACT

Examples of a substrate processing apparatus include a chamber, a shielding component that is a susceptor or an upper cover provided in the chamber, and a bevel mask that is provided in the chamber and has an inclined surface on which a vertical distance from the shielding component increases toward a center side of the shielding component.

This application claims the benefit of and priority to U.S. Patent Application No. 62/945,061 filed on Dec. 6, 2019, in the United States Patent and Trademark Office, the disclosure of which is incorporated by reference herein in its entirety.

### TECHNICAL FIELD

Examples are described which relate to a substrate processing apparatus, a bevel mask and a substrate processing method.

### BACKGROUND

For example, formation of a film on the front side of a substrate may cause the substrate to be warped. In order to suppress the warpage of the substrate, a highly stressed film may be formed on the back side of the substrate. At this time, in order to perform processing on the back side of the substrate while suppressing processing on the front side of the substrate, a bevel mask may be made close to a bevel of the substrate. According to one example, the bevel mask has been used to suppress film formation on the front side of a substrate. If the bevel mask conceals or chucks an outer edge of the back side of the substrate, it would be impossible to perform uniform processing on the back side of the substrate. For example, when a film is formed on the back side of a substrate, the film thickness in a region of several mm inside the bevel on the substrate is smaller than the film thickness in the center of the substrate. The inability to perform uniform processing on the back side of the substrate makes it impossible to completely chuck the substrate in subsequent steps, or causes pattern misalignment, defective film formation or the like.

### SUMMARY

Some examples described herein may address the above-described problems. Some examples described herein may provide a substrate processing apparatus, a bevel mask and a substrate processing method that enable substantially uniform processing to be performed on the back side of a substrate while suppressing processing on the front side of the substrate in substrate processing using a bevel mask.

In some examples, a substrate processing apparatus includes a chamber, a shielding component that is a susceptor or an upper cover provided in the chamber, and a bevel mask that is provided in the chamber and has an inclined surface on which a vertical distance from the shielding component increases toward a center side of the shielding component.

### BRIEF DESCRIPTION OF THE DRAWINGS

FIG. 1 is a cross-sectional view of a substrate processing apparatus;

FIG. 2 is a bottom view of the bevel mask;

FIG. 3 is a cross-sectional view of the substrate processing apparatus;

FIG. 4 is an enlarged view of the bevel mask and its vicinity;

FIG. 5 is a cross-sectional view showing a bevel mask according to another example;

FIG. 6 is a cross-sectional view showing a bevel mask according to another example;

FIG. 7 is a cross-sectional view showing a bevel mask according to another example;

FIG. 8 is a cross-sectional view showing a bevel mask according to another example;

FIG. 9 is a cross-sectional view of a substrate processing apparatus according to another example; and

FIG. 10 is an enlarged view of the bevel mask and its vicinity.

### DETAILED DESCRIPTION

A substrate processing apparatus, a bevel mask, and a substrate processing method will be described with reference to the drawings. The same or corresponding components are represented by the same reference signs, and repeated description thereof may be omitted.

### Embodiment

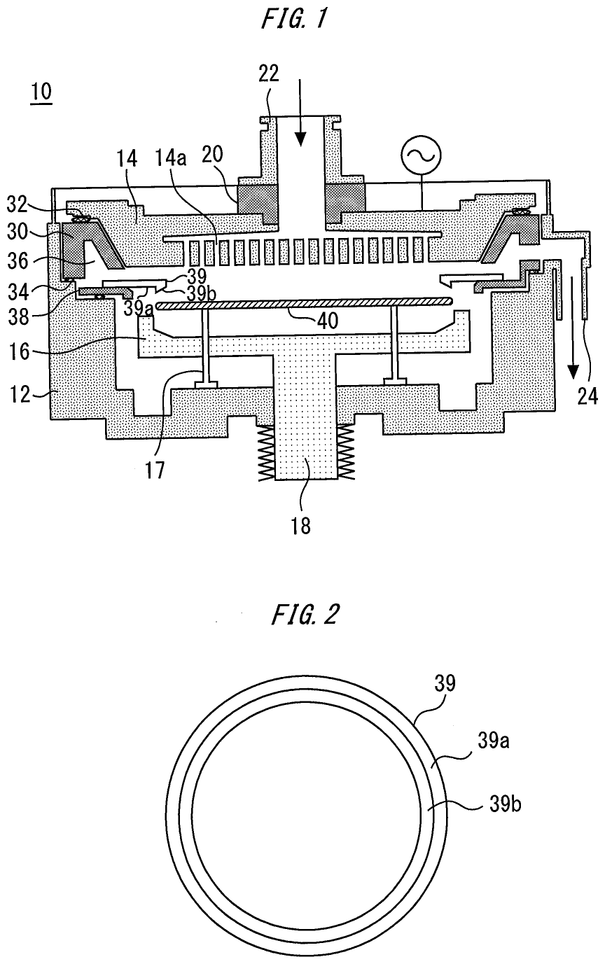

FIG. 1 is a cross-sectional view showing a configuration example of a substrate processing apparatus 10 according to one example. The substrate processing apparatus 10 includes a susceptor 16 provided in a chamber 12. The susceptor 16 is fixed to a shaft 18. The shaft 18 is moved up and down by a lifting mechanism, which also enables up-and-down movement of the susceptor 16. A susceptor pin 17 fixed to the chamber 12 protrudes above the upper surface of the susceptor 16 when the susceptor 16 is located on a lower side. Furthermore, the susceptor pin 17 is positioned below the susceptor 16 when the susceptor 16 is located on an upper side, and thus it does not protrude above the upper surface of the susceptor 16.

A shower plate 14 is placed above the susceptor 16. The shower plate 14 is provided with a plurality of slits 14a. A gas introduction pipe 22 is fixed to the shower plate 14 via an insulating component 20. Arbitrary gas supplied from a gas source is passed through the gas introduction pipe 22 and the slits 14a, and provided to a space above the susceptor 16. A gas supply direction is indicated by an arrow.

A parallel plate structure is provided by the susceptor 16 and the shower plate 14 described above. High-frequency power is applied to the shower plate 14 while providing gas to the space between the susceptor 16 and the shower plate 14, whereby plasma can be generated in this space.

A flow control ring (FCR) 38 is placed on the chamber 12, for example, via an O-ring. An exhaust duct 30 is placed on the chamber 12, for example, via an O-ring 34. The exhaust duct 30 can be formed of an insulator such as ceramic. Furthermore, the shower plate 14 is placed on the exhaust duct 30, for example, via an O-ring 32, whereby the chamber 12 and the shower plate 14 are electrically insulated from each other. An exhaust passage 36 having an annular shape in plan view is provided by the exhaust duct 30 and the FCR 38. This exhaust passage 36 is connected to an exhaust duct 24. A vacuum pump, a valve, and the like, which make it possible to perform pressure adjustment in the chamber 12 are provided in the middle of the exhaust duct 24 or in the end portion of the exhaust duct 24.

A bevel mask 39 is placed on the FCR 38 in the chamber 12. The bevel mask 39 is a ring formed in an annular shape in plan view. The material of the bevel mask 39 is, for example, AlN, but may be any insulator. The bevel mask 39 includes a flat surface 39a and an inclined surface 39b inside the flat surface 39a. In the example of FIG. 1, the bevel mask 39 is placed on the FCR 38 with the flat surface 39a being in contact with the upper surface of the FCR 38. The inclined surface 39b is a surface on which the vertical distance from the susceptor 16 increases toward the center side of the susceptor 16. In other words, the inclined surface 39b is a surface which is non-parallel to the horizontal direction and is higher toward the center of a portion surrounded by the bevel mask 39.

FIG. 2 is a bottom view of the bevel mask 39. According to an example, the bevel mask 39 includes a flat surface 39a and an inclined surface 39b which is connected to the flat surface 29a and located inside the flat surface 39a. The inclined surface 39b may be formed in an annular shape in plan view and in bottom view.

Next, a substrate processing method using the substrate processing apparatus 10 will be described. First, as shown in FIG. 1, a substrate 40 is introduced into the chamber 12, and placed on the susceptor pins 17. For example, a wafer transfer arm holding the substrate 40 is introduced into the chamber 12, and the arm is moved down above the susceptor pins, thereby placing the substrate 40 on the susceptor pins 17.

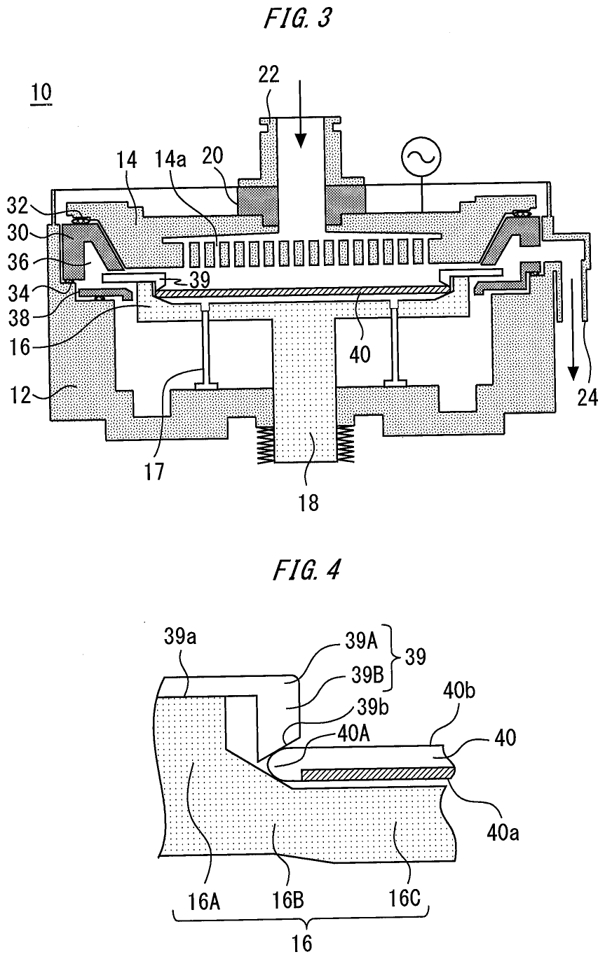

Next, the susceptor 16 and the shaft 18 are raised by a lifting mechanism provided outside the chamber 12. FIG. 3 is a cross-sectional view showing a configuration example of the substrate processing apparatus in a state where the susceptor 16 is raised. When the susceptor 16 is raised, the susceptor 16 and the substrate 40 come into contact with each other, and the substrate 40 separates from the susceptor pins 17. During the upward movement of the susceptor 16, the susceptor 16 and the bevel mask 39 come into contact with each other, and the bevel mask 39 separates from the FCR 38. Then, as shown in FIG. 3, the substrate 40 and the bevel mask 39 are supported by the susceptor 16.

FIG. 4 is an enlarged view of the bevel mask 39 of FIG. 3 and its vicinity. According to one example, the substrate 40 has a device surface 40a that is a surface on which a device is formed, and a back side 40b which is a surface opposite to the device surface 40a. An inclined portion at the outer edge portion of the substrate 40 is a bevel 40A. The device surface 40a is subjected to a well-known semiconductor process to form a device, and as a result, the substrate 40 may be warped to some extent.

In the example of FIG. 4, the susceptor 16 includes an upward convex portion 16A, an intermediate portion 16B, and a central portion 16C. Of the three portions, the upper surface of the upward convex portion 16A is the highest. The intermediate portion 16B is a slope which decreases in height from the upward convex portion 16A to the central portion 16C. The upper surface of the central portion 16C is a flat surface.

In the example of FIG. 4, the bevel mask 39 includes a main body portion 39A and a convex portion 39B at the lower surface on an inner edge side of the main body portion 39A. In this example, the bevel mask 39 is placed on the susceptor 16 with the flat surface 39a being in contact with the upward convex portion 16A. Further, the inclined surface 39b is in contact with the bevel 40A. In this example, the bevel mask 39 is in contact with only the bevel 40A, and is in contact with neither the back side 40b nor the device surface 40a. For example, by bringing the inclined surface 39b into contact with the bevel 40A, the warped substrate 40 can be pressed against the susceptor 16. According to another example, the inclined surface 39b is in proximity to the bevel 40A, but not in contact with the bevel 40A. In that case, an inclined surface is provided slightly above the inclined surface 39b of FIG. 4. As a result, there is no contact between the bevel mask 39 and the substrate 40.

As described above, the substrate 40 is placed on the susceptor 16 so that the device surface 40a and the susceptor 16 face each other. Next, after the susceptor is moved to a process position as necessary, the back side 40b is subjected to a plasma treatment. Gas supply to the space between the susceptor 16 and the shower plate 14 and application of high-frequency power to the shower plate 14 are performed alternately or simultaneously. By generating plasma in this space, film formation on the back side 40b, etching processing on the back side 40b, modification of the film on the back side 40b or the like is performed. According to one example, this plasma treatment is applied to the entire back side 40b. However, since the bevel mask 39 is in contact with or in proximity to the bevel 40A, there is no significant plasma treatment on the bevel 40A. According to an example, it is possible to avoid occurrence of any step on the back side by forming a film on the entire back side 40b with the plasma treatment.

In the above example, plasma is generated by the parallel plate structure, but plasma can be generated by another method. In the example of FIG. 1, the shower plate 14 is adopted as a plasma unit provided in connection with the susceptor. However, a well-known microwave plasma generation apparatus or a well-known inductively coupled plasma apparatus can be adopted as the plasma unit as described above.

FIG. 5 is a cross-sectional view showing a bevel mask 39 according to another example. The inclined surface of the lower surface of the convex portion 39B includes a flat inclined surface 39b and a concave curved surface 39c. The curved surface 39c is a surface which is in contact with or in proximity to the bevel 40A. According to an example, the curved surface 39c enables surface contact between the convex portion 39B and the bevel 40A, or suppresses gas intrusion through the gap between the convex portion 39B and the bevel 40A.

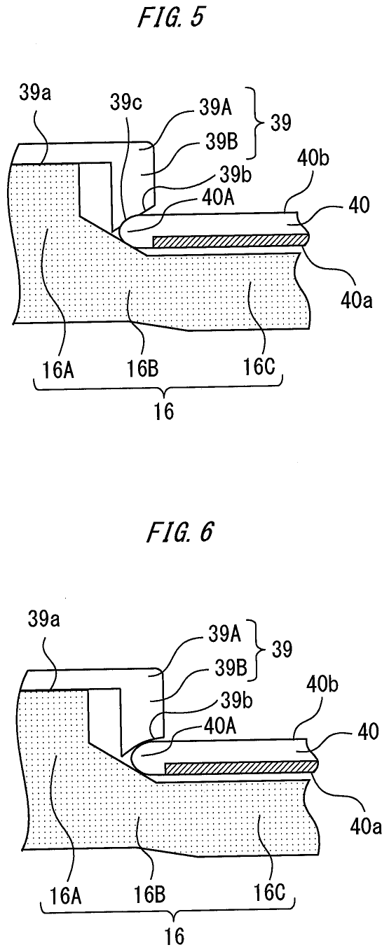

FIG. 6 is a cross-sectional view showing a bevel mask 39 according to another example. A concave curved surface 39d is provided as the inclined surface of the lower surface of the convex portion 39B. In this example, the entire lower surface of the convex portion 39B serves as the curved surface 39d. Therefore, even when the substrate 40 is misaligned, the curved surface 39d and the bevel 40A can be brought into contact with or proximity to each other.

By making the curvatures of the curved surfaces of FIGS. 5 and 6 be coincident with or close to the curvature of the bevel 40A, it is possible to further suppress the intrusion of gas through the gap between the convex portion 39B and the bevel 40A.

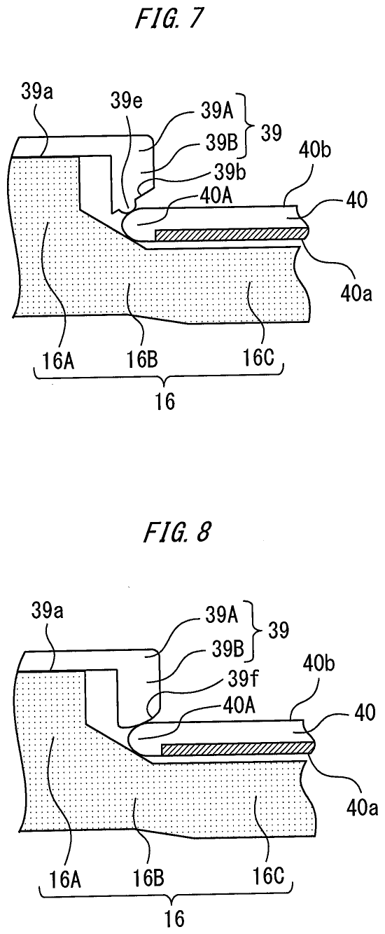

FIG. 7 is a cross-sectional view showing a bevel mask 39 according to another example. An inclined surface 39b and a convex curved surface 39e are provided as the inclined surface of the lower surface of the convex portion 39B. The convex curved surface 39e is a surface that is in contact with or in proximity to the bevel 40A.

FIG. 8 is a cross-sectional view showing a bevel mask 39 according to another example. A convex curved surface 39f is provided as the inclined surface of the lower surface of the convex portion 39B. The entire lower surface of the convex portion 38B serves as a convex curved surface 39f.

According to the examples of FIGS. 7 and 8, by providing the convex curved surface 39e or the convex curved surface 39f, the bevel mask 39 and the bevel 40A can be surely brought into contact with or made sufficiently close to each other.

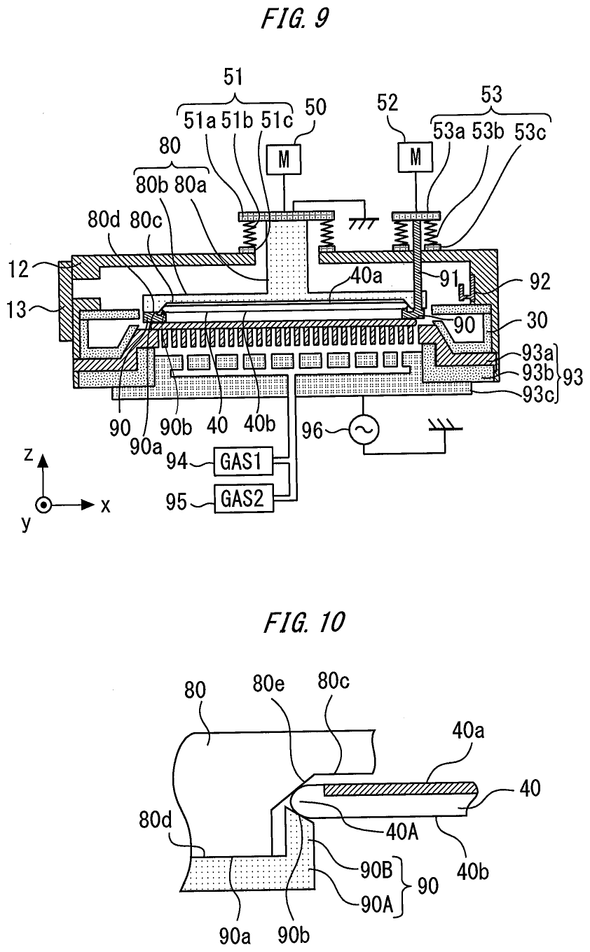

FIG. 9 is a cross-sectional view of a substrate processing apparatus according to another example. This substrate processing apparatus is a parallel plate type plasma processing apparatus. A door 13 is attached to a chamber 12 so as to be able to provide a substrate to inside of the chamber 12 or take out a substrate from the chamber 12. The chamber 12 can be provided as part of a Dual Chamber Module (DCM) or part of a Quad Chamber Module (QCM). An upper cover 80 is provided inside the chamber 10. According to an example, the upper cover 80 is provided as a ground electrode. The ground electrode is an electrode for grounding.

The upper cover 80 includes a shaft portion 80a and a disk portion 80b connected to the shaft portion 80a. The shaft portion 80a is fixed at a first lifting mechanism 51 which can move in a z positive-negative direction. According to an example, the first lifting mechanism 51 is provided by a plate 51a fixed at the shaft portion 80a being fixed at an upper end of a bellows 51b, and a plate 51c fixed at the chamber 12 being fixed at a lower end of the bellows 51b. As the first lifting mechanism 51, various configurations which move the upper cover 80 up and down inside the chamber 10 can be employed.

The disk portion 80b has a circular shape or a substantially circular shape in planar view. A lower surface of the disk portion 80b which is a lower surface of the upper cover 80 has, for example, a first lower surface 80c, and a second lower surface 80d which surrounds the first lower surface 80c and which is located below the first lower surface 80c. Therefore, the lower surface of the disk portion 80b has a shape having a dent at the center.

The upper cover 80 which is a ground electrode, functions as an upper electrode in a parallel plate structure. To enable plasma coupling and prevent or reduce electric discharge, a difference in height between the first lower surface 80c and the second lower surface 80d can be made, for example, equal to or less than 1 mm.

A bevel mask 90 is provided inside the chamber 12. The bevel mask 90 includes a flat surface 90a, and an inclined surface 90b surrounded by the flat surface 90a. The inclined surface 90b is a surface on which the vertical distance from an upper cover 80 increases toward the center side of the upper cover 80. In other words, the inclined surface 90b is a surface which is non-parallel to the horizontal direction and decreases in height toward the center of a portion surrounded by the bevel mask 90.

According to an example, the bevel mask 90 is supported or suspended by a support bar 91. The support bar 91 is fixed to a second lifting mechanism 53 that is driven by a motor 52. The second lifting mechanism 53 is configured to move the support bar 91 and the bevel mask 90 up and down inside the chamber 10. In other words, the support bar 91 and the bevel mask 90 can be moved up and down by the motor 52 and the lifting mechanism 53. According to an example, the second lifting mechanism 53 is provided by a plate 53a fixed at the support bar 91 being fixed at the upper end of the bellows 53b, and a plate 53c fixed at the chamber 12 being fixed at the lower end of the bellows 53b. As the second lifting mechanism 53, various configurations which moves the bevel mask 90 up and down inside the chamber 12 can be employed.

The support bar 91 and the bevel mask 90 can be formed as one body with, for example, a dielectric body. The bevel mask 90 has an annular shape in planar view. The bevel mask 90 includes an annular flat surface 90a and a inclined surface 90b located immediately below the upper cover 80. In some examples, as shown in FIG. 9, a height of the flat surface 90a is equal to or higher than a height of the inclined surface 90b. A difference in height between the flat surface 90a and the inclined surface 90b is, for example, greater than a thickness of the substrate 40 to be processed. According to another example, as shown in FIG. 10, a height of the flat surface 90a may be lower than a height of the inclined surface 90b.

FIG. 10 is an enlarged view of the bevel mask 90 and its vicinity. The bevel mask 90 includes a main body portion 90A and a convex portion 90B at the upper surface on an inner edge side of the main body portion 90A. The main body portion 90A has the flat surface 90a, and the convex portion 90B has the inclined surface 90b. The inclined surface 90b is an inclined surface on which the vertical distance from the main body portion 90A decreases toward the center side of the bevel mask 90. In some examples, slanted third lower surface 80e contacts the bevel 40A. According to another examples, the third lower surface 80e is omitted so that the upper cover 80 does not contact the substrate 40.

The inclined surface 90b is in contact with the bevel 40A, whereby the substrate 40 is supported by the bevel mask 90. According to an example, the bevel mask 90 contacts only the bevel 40A of the substrate 40, and does not contact any part of the substrate 40 other than the bevel 40A. Therefore, the back side 40b of the substrate 40 is exposed, so that the plasma treatment can be performed on the entire back side 40b. The inclined surfaces having various shapes described above can be adopted as the inclined surface 90b.

FIG. 9 illustrates a rotating arm 92 located in the vicinity of an inner wall of the chamber 12. The rotating arm 92 is provided to transfer the substrate to inside of four chambers which constitute, for example, the QCM. The substrate processing apparatus includes a plasma unit which is configured to generate plasma in a region below the upper cover 80 and the bevel mask 90. In the example in FIG. 9, the plasma unit includes a shower plate 93, gas sources 94 and 95 and an RF power supply 96. The shower plate 93 is provided below the upper cover 80 so as to face the upper cover 80. The shower plate 93 includes plates 93a and 93c which have slits for providing gas in a z positive direction from the gas sources 94 and 95, and a spacer 93b provided between the plates 93a and 93b. The whole of the shower plate 93 can be formed with a metal. According to another example, at least the plate 93c is formed with a metal. The gas sources 94 and 95 provide gas necessary for plasma processing. The RF power supply 96 provides high-frequency power for putting gas into a plasma state, to the shower plate 93. In this manner, the substrate processing apparatus can perform plasma processing with a parallel plate structure including the upper cover 80 and the shower plate 93.

In some examples, the upper cover 80 is evacuated upward by, for example, a motor 50 moving the first lifting mechanism 51. Further, the bevel mask 90 is evacuated upward by, for example, a motor 52 moving the second lifting mechanism 53. Thereafter, a support pin which is part of the rotating arm 92 is provided to a substrate receiving position inside the chamber 12 by the rotating arm 92 rotating. Support pins for supporting the substrate are provided to one of the four chambers by the rotating arm 92 rotating. The support pins may be disposed at positions surrounded by the bevel mask 90. Then, after the bevel mask 90 is moved downward below upper ends of the support pins, the substrate is put on the support pins provided immediately below the upper cover 80. Then, the inclined surface 90b is brought into contact with the bevel 40A by the bevel mask 90 being moved upward. As the result of this contact, the support pins are separated from the substrate 40, and are evacuated from positions immediately below the upper cover 80 by the rotating arm 92 rotating.

Then, the flat surface 90a is brought into close contact with the upper cover 80 while contact between the upper cover 80 and the substrate 40 is avoided. In this example, the flat surface 90a is brought into close contact with the second lower surface 80d by the upper cover 80 being moved downward. According to an example, it is possible to prevent contact between the upper cover 80 and the substrate 40 by providing the first lower surface 80c located above the second lower surface 80d.

The flat surface 90a is located immediately below the second lower surface 80d, and, when the second lower surface 80d comes into contact with the flat surface 90a, flow of gas through space between the upper cover 80 and the bevel mask 90 is inhibited. In another example, in a case where a lower surface of the disk portion 80b of the upper cover 80 is made flat, as a result of the lower surface of the upper cover contacting the flat surface 90a, flow of gas through space between the lower surface of the upper cover 80 and the flat surface 90a is inhibited.

In some examples, space surrounded by the substrate 40, the bevel mask 90 and the upper cover 80 becomes enclosed space. In this case, gas supplied from the gas sources 94 and 95 and plasma provided between parallel plates are not virtually provided to the enclosed space.

Then, plasma processing is performed on the back side 40b of the substrate 40. In some examples, it is possible to protect the device surface 40a by avoiding contact between the substrate 40 and the upper cover 80. It is possible to ensure this avoidance of contact by providing a concave portion on the lower surface of the upper cover 80. According to an example, the film formed at the back surface 40b of the substrate 40 through the plasma processing alleviates warpage of the substrate 40.

In some of the foregoing examples, a shielding component which is the susceptor or the upper cover faces the device surface of the substrate. When the shielding component is the susceptor, the susceptor 16 and the substrate 40 are in contact with each other, and the contact between the bevel 40A of the substrate 40 and the bevel mask 39 may be not essential. On the other hand, when the shielding component is the upper cover 80, the bevel mask 90 and the bevel 40A of the substrate 40 are in contact with each other, and the contact between the substrate 40 and the upper cover 80 may be not essential.

At least partially inclined surface of the bevel mask described in each of the foregoing examples may be circular in bottom view, or may have a shape with consideration for a notch or an orientation flat. Specifically, the inclined surface of the bevel mask can be adjusted so that the notch or the orientation flat and the inclined surface of the bevel mask can be brought into contact with or proximity to each other.

1. A substrate processing apparatus comprising:
a chamber;
a shielding component that is a susceptor or an upper cover provided in the chamber; and
a bevel mask that is provided in the chamber and has an inclined surface on which a vertical distance from the shielding component increases toward a center side of the shielding component.

2. The substrate processing apparatus according to claim 1, wherein the inclined surface is formed in an annular shape in plan view.

3. The substrate processing apparatus according to claim 1, wherein the inclined surface has a flat surface.

4. The substrate processing apparatus according to claim 1, wherein the inclined surface has a concave curved surface.

5. The substrate processing apparatus according to claim 1, wherein the inclined surface has a convex curved surface.

6. The substrate processing apparatus according to claim 1, further comprising a flow control ring in contact with a lower surface of the bevel mask.

7. The substrate processing apparatus according to claim 1, further comprising a lifting mechanism for moving the bevel mask up and down.

8. The substrate processing apparatus according to claim 1, further comprising a plasma unit provided in connection with the shielding component.

9. The substrate processing apparatus according to claim 1, wherein the shielding component is the susceptor, and the bevel mask has a flat surface that is configured to be in contact with an upper surface of the susceptor outside the inclined surface.

10. A bevel mask comprising:
a main body portion having an annular shape; and
a convex portion at a lower surface or upper surface on an inner edge side of the main body portion, wherein the convex portion has an inclined surface on which a distance from the main body portion decreases toward a center side of the bevel mask.

11. The bevel mask according to claim 10, wherein the inclined surface is formed in an annular shape in plan view.

12. The bevel mask according to claim 10, wherein the inclined surface has a flat surface.

13. The bevel mask according to claim 10, wherein the inclined surface has a concave curved surface.

14. The bevel mask according to claim 10, wherein the inclined surface has a convex curved surface.

15. A substrate processing method for a substrate having a device surface that is a surface on which a device is formed, and a back side that is a surface opposite to the device surface, comprising:
causing the device surface to face a shielding component that is a susceptor or an upper cover;
bringing an inclined surface of a bevel mask into contact with or proximity to a bevel of the substrate; and
subjecting the back side to a plasma treatment.

16. The substrate processing method according to claim 15, wherein the plasma treatment is performed all over the back side.
